(19) United States
(12) Patent Application Publication
(10) Pub. No.: US 2020/0044621 A1
(43) Pub. Date: Feb. 6, 2020

(54) THIN FILM DEVICES

(71) Applicant: QUALCOMM Incorporated, San Diego, CA (US)

(72) Inventors: Stephen Alan FANELLI, San Marcos, CA (US); Sinan GOKTEPELI, San Diego, CA (US); Alexandre Augusto SHIRAKAWA, San Diego, CA (US)

(21) Appl. No.: 16/050,212

(22) Filed: Jul. 31, 2018

(51) Int. Cl. H03H 3/10; H03H 9/02; H01L 41/312; H01L 41/338

(52) U.S. Cl. CPC H03H 3/10; H03H 9/02559; H01L 41/338; H03H 9/02897; H01L 41/312; H03H 9/02834

(57) ABSTRACT

In certain aspects, a thin film surface acoustic wave (SAW) die comprises a high-resistivity substrate, a bonding layer on the high-resistivity substrate, and a thin film piezoelectric island on the bonding layer, where an edge of the thin film piezoelectric island is offset from an edge of the bonding layer.

### BACKGROUND

### Field

Aspects of the present disclosure relate to thin film devices, and more particularly, to structures and manufacturing methods for thin film devices on high resistivity silicon substrate.

### Background

In some examples, a layer transfer process is used to transfer a top active device portion of a silicon-on-insulator (SOI) wafer to a handle wafer. In this process, the top portion of the SOI wafer is bonded to the handle wafer. The same process may be used for building a thin film device, such as a thin film surface acoustic wave (SAW), on a high-resistivity substrate. For example, a thin film piezoelectric wafer may be bonded with a high-resistivity silicon handle wafer. However, if two bonded wafers have different thermal expansion coefficients, fracture may happen when the bonded wafer pair is annealed or processed at higher temperatures. Accordingly, it would be beneficial to have structures and methods for thin film devices on a high resistivity substrate that can better tolerate thermal cycles during manufacturing.

### SUMMARY

The following presents a simplified summary of one or more implementations to provide a basic understanding of such implementations. This summary is not an extensive overview of all contemplated implementations, and is intended to neither identify key nor critical elements of all implementations nor delineate the scope of any or all implementations. The sole purpose of the summary is to present concepts relate to one or more implementations in a simplified form as a prelude to a more detailed description that is presented later.

In one aspect, a thin film surface acoustic wave (SAW) die comprises a high-resistivity substrate, a bonding layer on the high-resistivity substrate, and a thin film piezoelectric island on the bonding layer, wherein an edge of the thin film piezoelectric island is offset from an edge of the bonding layer.

In another aspect, an apparatus comprises a high-resistivity substrate, a bonding layer on the high resistive substrate, and a plurality of thin film piezoelectric islands on the bonding layer.

In another aspect, a method comprises providing a piezoelectric wafer having a front surface and a back surface; forming an exfoliation layer in the piezoelectric wafer from the front surface; forming a plurality of trenches on the piezoelectric wafer from the front surface to form a plurality of piezoelectric islands; bonding the piezoelectric wafer from the front surface to a high-resistivity wafer though a bonding layer; and removing a portion of the piezoelectric wafer between the back surface and the exfoliation layer.

To accomplish the foregoing and related ends, one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIGS. 1a-1e illustrate an exemplary process flow in making an exemplary thin film piezoelectric wafer on a high-resistivity substrate according to certain aspects of the present disclosure.

FIG. 2 illustrates an exemplary product with a thin film piezoelectric wafer on a high-resistivity substrate according to certain aspects of the present disclosure.

FIG. 3 illustrates another exemplary product with a thin film piezoelectric wafer on a high-resistivity substrate according to certain aspects of the present disclosure.

FIGS. 4a-4b illustrate an exemplary thin film surface acoustic wave (SAW) die according to certain aspects of the present disclosure.

FIG. 5 illustrates another exemplary product with a thin film piezoelectric wafer on a high-resistivity substrate according to certain aspects of the present disclosure.

FIGS. 6a-6b illustrate another exemplary thin film surface acoustic wave (SAW) die according to certain aspects of the present disclosure.

FIG. 7 illustrates an exemplary method in making thin film surface acoustic wave (SAW) dies according to certain aspects of the present disclosure.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing an understanding of the various concepts. However, it will be apparent to those skilled in the art that these concepts may be practiced without these specific details. In some instances, well-known structures and components are shown in block diagram form in order to avoid obscuring such concepts.

A surface acoustic wave (SAW) is an acoustic wave traveling along the surface of a material exhibiting elasticity, with an amplitude that typically decays exponentially with depth into the substrate. SAW devices are used as filters, oscillators, transformers and sensors. SAW filters are now used in mobile telephones. They provide significant advantages in performance, cost, and size over other filter technologies such as quartz crystals (based on bulk waves), LC filters, and waveguide filters.

The function of a SAW device is based on the transduction of acoustic waves. There are two dimensional waves confined to the surface of the solid material, down to a depth of approximately two wavelengths. The transduction from electric energy to mechanical energy (in the form of SAWs) is often accomplished by the use of piezoelectric materials. The piezoelectric layer is usually thin and need to be placed on top of a carrier, such as a high-resistivity silicon handle wafer. However, if the thin piezoelectric layer and the carrier have different thermal expansion coefficients, the thin piezoelectric layer may be fractured during the thermal cycles, such as during an annealing process. Accordingly, it would be beneficial to have structures and methods for thin film devices on a high-resistivity substrate that can better tolerate thermal cycles during manufacturing.

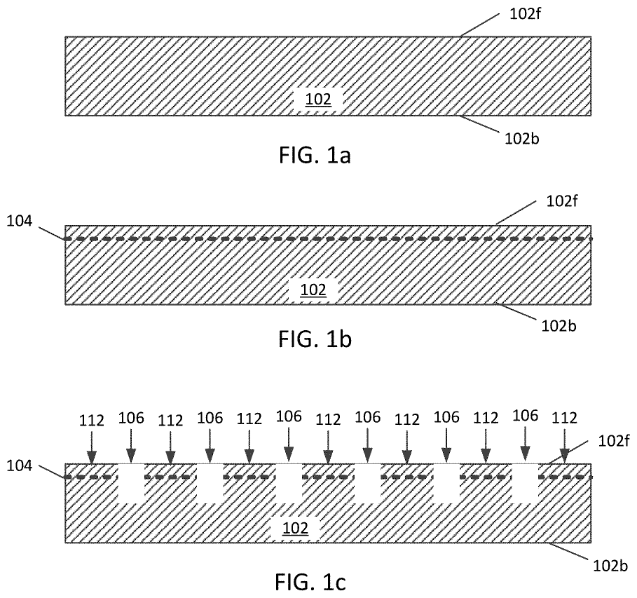

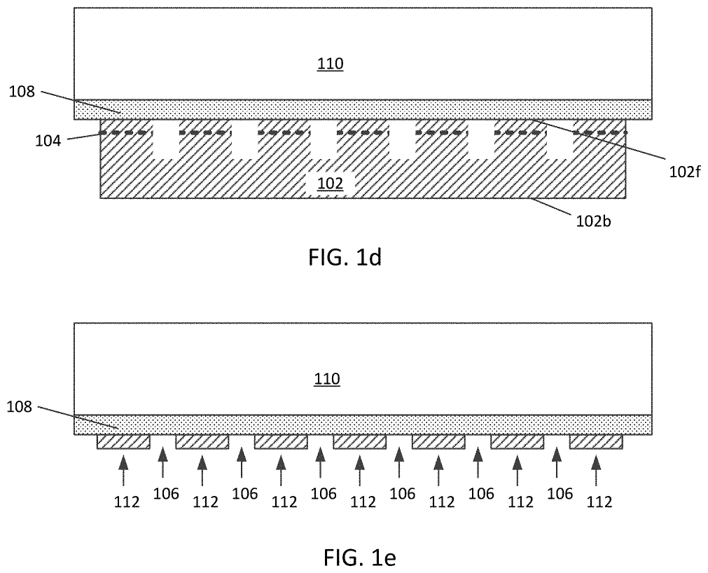

FIGS. 1a-1e illustrate an exemplary process flow in making an exemplary thin film piezoelectric wafer on a high-resistivity substrate according to certain aspects of the present disclosure. In FIG. 1a, a piezoelectric wafer 102 is provided. The piezoelectric wafer 102 comprises piezoelectric material, such as lithium tantalite or lithium niobate. The piezoelectric wafer 102 has a front surface 102f and a back surface 102b. The starting piezoelectric wafer 102 is relatively thick so it can stand by itself.

In FIG. 1b, an exfoliation layer 104 is formed closed to the front surface 102f in the piezoelectric wafer 102. The exfoliation layer 104 may be formed by performing high dose ion implantation from the front surface 102f. The depth of the exfoliation layer 104 defines the thickness of the thin film devices in the final products.

In FIG. 1c, a plurality of trenches 106 is formed from the front surface 102f of the piezoelectric wafer 102. The depth of the plurality of trenches 106 may be larger than the depth of the exfoliation layer 104. The plurality of trenches 106 may be formed by dry etch, wet etch, laser ablation, or other suitable methods. A plurality of piezoelectric islands 112 is formed among the plurality of trenches 106.

In FIG. 1d, the piezoelectric wafer 102 is bonded to a high-resistivity substrate 110 through a bonding layer 108. The high-resistivity substrate 110 may be low doped or undoped silicon, porous silicon, glass, sapphire, etc., with resistivity greater than or equal to 3 KΩ. The high-resistivity substrate 110 serves as handle wafer or carrier substrate in the final product. The bonding layer 108 may be trap-rich layer. It could be oxide film if the high-resistivity substrate 110 is a silicon wafer. The bonding layer 108 may be SiCN for other types of high-resistivity substrate 110. Certain thermal cycle, such as an anneal process, is needed to facilitate the bonding.

The plurality of trenches 106 in the piezoelectric wafer 102 serves as stress relief during subsequent thermal cycles. In the subsequent thermal cycles, such as high temperature processes or anneal processes, the effect of the thermal coefficient mismatch between the high-resistivity substrate 110 and the piezoelectric wafer 102 is localized, limited to each individual piezoelectric island 112, thus minimizing the damaging effect aggregation across the whole wafer.

In FIG. 1e, a portion of piezoelectric wafer may be removed through exfoliation process. The piezoelectric wafer 102 may first be ground from the back surface 102b (ground away thus not shown) to expose the plurality of trenches 106. Then the piezoelectric wafer 102 may go through another thermal cycle, such as anneal at 100-450° C. temperature to exfoliate along the exfoliation layer 104. Chemical mechanical polishing (CMP) is further applied to remove the implant damage and to thin the piezoelectric wafer 102 to a desire thickness. As a result, the plurality of piezoelectric islands 112 (a thinned version) is left on top of the high-resistivity substrate 110 through the bonding layer 108. The plurality of piezoelectric islands 112 is isolated from each other by the plurality of trenches 106.

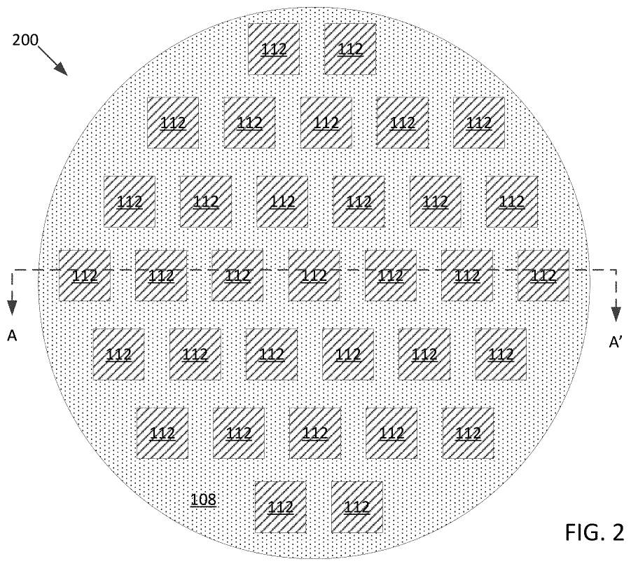

FIG. 2 illustrates an exemplary product with a thin film piezoelectric wafer on a high-resistivity substrate according to certain aspects of the present disclosure. FIG. 2 is a top-down illustration of the product 200 using the process flow illustrated in FIGS. 1a-1e. FIG. 1e is the cross-section of FIG. 2 along the line A-A′. The product 200 comprises the plurality of piezoelectric islands 112 on the high-resistivity substrate 110 bonded through the bonding layer 108. Between the plurality of piezoelectric islands 112 is the plurality of trenches 106. In certain aspects, the plurality of trenches 106 may be all linked together as illustrated in FIG. 2. In certain aspects, only a portion of the plurality of trenches 106 are linked.

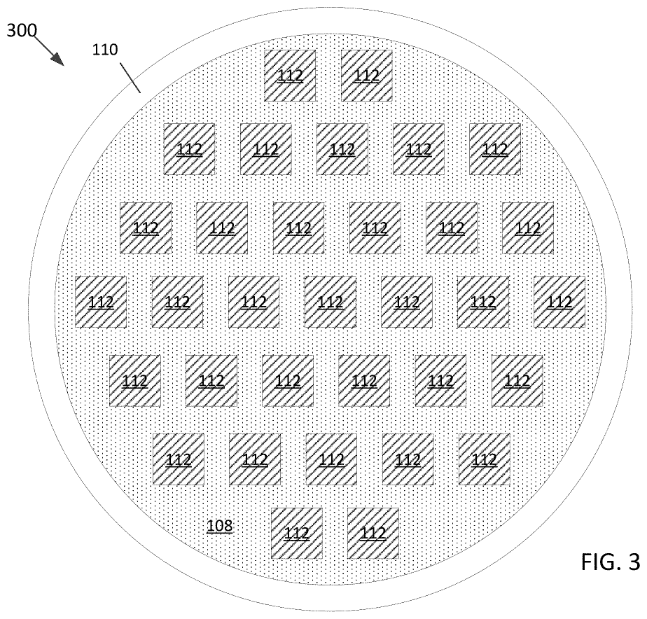

FIG. 3 illustrates another exemplary product with a thin film piezoelectric wafer on a high-resistivity substrate according to certain aspects of the present disclosure. Like FIG. 2, The product 300 comprises the plurality of piezoelectric islands 112 on the high-resistivity substrate 110 bonded through the bonding layer 108. In addition, the piezoelectric wafer 102 and the bonding layer 108 are edge trimmed, opening a ring to expose the high-resistivity substrate 110 around the edge of the wafer. The outer edge of the piezoelectric wafer 102 typically has a lower bonding strength and often the H+ implant does not have the correct implant dose for exfoliation in this region. Trimming away the edge help remove the less ideal portion.

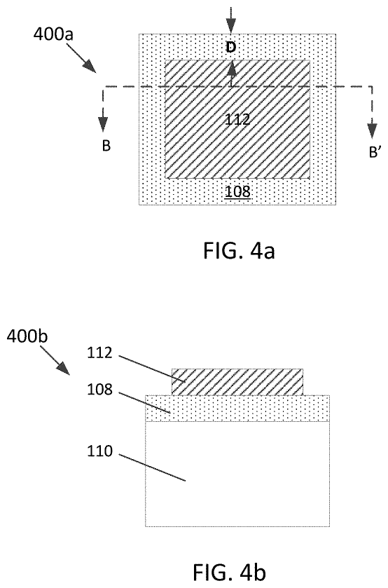

FIGS. 4a-4b illustrate an exemplary thin film surface acoustic wave (SAW) die according to certain aspects of the present disclosure. FIG. 4b is a cross-section of FIG. 4a along line B-B′. After the completion of the process flow shown in FIGS. 1a-1e, the product 200 or the product 300 is diced to obtain a plurality of dies. Each die is an individual SAW die. A plurality of individual SAW dies 400a is thus obtained. Each of the plurality of individual SAW dies 400a comprises a portion of the high-resistivity substrate 110, a portion of the bonding layer 108 on the high-resistivity substrate 110, and a thin film piezoelectric island 112 on the bonding layer 108. The edge of the thin film piezoelectric island 112 is offset from the edge of the bonding layer 108 by an amount of D. This offset D comes from the stress-relief trenches 106 during the manufacturing.

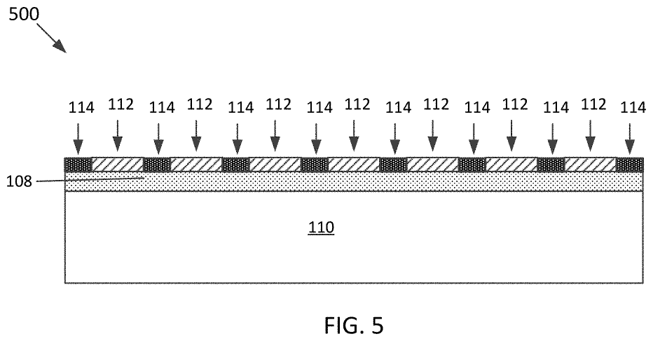

FIG. 5 illustrates another exemplary product with a thin film piezoelectric wafer on a high-resistivity substrate according to certain aspects of the present disclosure. Like FIG. 1e, the product 500 comprises the high-resistivity substrate 110, the bonding layer 108 on the high-resistivity substrate 110, and the plurality of piezoelectric islands 112 on the bonding layer 108. In addition, between any two piezoelectric islands 112, a thermal dielectric material 114 is filled. A typical thermal material may be PECVD silicon dioxide or nitride or oxynitride. In the other words, a plurality of thermal dielectric materials 114 fills the plurality of trenches 106. The plurality of thermal dielectric materials 114 may be selected such that the average temperature coefficient of the plurality of thermal dielectric materials 114 and the plurality of piezoelectric islands 112 substantially matches or is close to the temperature coefficient of the high-resistivity substrate 110 and/or the bonding layer 108. Another good material could be porous dielectric material (i.e., low-K material) to allow the plurality of piezoelectric islands 112 to expand relatively easily during the bonding annealing. In certain aspects, if the plurality of trenches 106 is linked together as illustrated in FIG. 2, the plurality of thermal dielectric materials 114 is linked together as well. In certain aspects, if only a portion of the plurality of trenches 106 are linked, then only a portion of the plurality of thermal dielectric materials 114 is linked.

The thermal dielectric material 114 provides support and protection to the plurality of piezoelectric islands in addition to providing a thermal buffer between two piezoelectric islands, resulting in better reliability and higher yield.

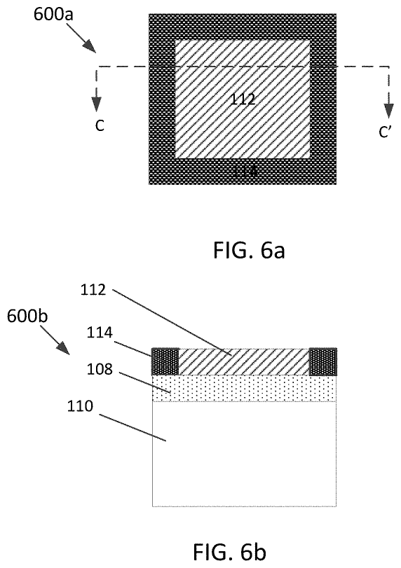

FIGS. 6a-6b illustrate another exemplary thin film surface acoustic wave (SAW) die according to certain aspects of the present disclosure. FIG. 6b is a cross-section of FIG. 6a along line C-C′. A plurality of individual SAW dies 600a is obtained by dicing the product 500 shown in FIG. 5. The individual SAW die 500a comprises a portion of the high-resistivity substrate 110, a portion of the bonding layer 108 on the high-resistivity substrate 110, and a thin film piezoelectric island 112 on the bonding layer 108. The edge of the thin film piezoelectric layer 112 is surrounded with suitable thermal dielectric material 114. The average temperature coefficient of the thermal dielectric material 114 and the thin film piezoelectric island 112 substantially matches an average temperature coefficient of the high-resistivity substrate 110. The thermal dielectric material 114 provides support and protection to the piezoelectric island 112 from subsequent thermal or other events, i.e., allowing the bonding wave to travel without being disrupted.

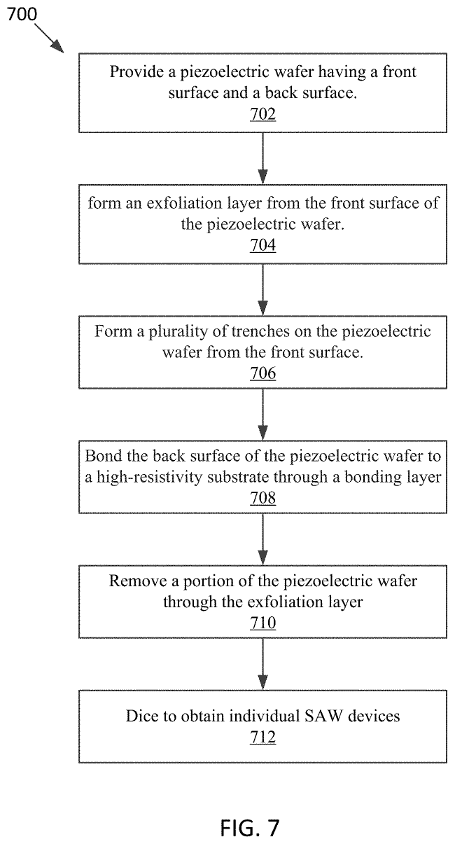

FIG. 7 illustrates an exemplary method 700 in making thin film surface acoustic wave (SAW) dies according to certain aspects of the present disclosure. At 702, a piezoelectric wafer (e.g., the piezoelectric wafer 102) is provided. The piezoelectric wafer comprises piezoelectric material, such as lithium tantalite or lithium niobate. The piezoelectric wafer has a front surface and a back surface. The piezoelectric wafer is relatively thick so it can stand by itself.

At 704, an exfoliation layer (e.g., the exfoliation layer 104) is formed closed to the front surface in the piezoelectric wafer. The exfoliation layer may be formed by performing high dose ion implantation from the front surface. The depth of the exfoliation layer defines the thickness of the thin film devices in the final products.

At 706, a plurality of trenches (e.g., the plurality of trenches 106) is formed from the front surface of the piezoelectric wafer. The depth of the plurality of the trenches may be larger than the depth of the exfoliation layer. The plurality of trenches may be formed by dry etch, wet etch, laser ablation, and/or other suitable methods. A plurality of piezoelectric islands (e.g., the plurality of piezoelectric islands 112) is formed among the plurality of trenches.

The plurality of trenches serves as stress relief during subsequent thermal cycles. In the subsequent thermal cycles, such as high temperature processes or anneal processes, the effect of the thermal coefficient mismatch between the high-resistivity substrate and the piezoelectric wafer is localized, limited to individual piezoelectric islands, thus minimizing the aggregation of the damaging effect across the whole wafer.

At 708, the piezoelectric wafer is bonded to a high-resistivity substrate (e.g., the high-resistivity substrate 110) through a bonding layer (e.g., the bonding layer 108). The high-resistivity substrate may be low doped or un-doped silicon, porous silicon, glass, sapphire, etc., with resistivity greater than or equal to 3 KΩ. The high-resistivity substrate serves as a handle wafer or carrier substrate in the final product. The bonding layer may be trap-rich layer. It could be oxide film if the high-resistivity substrate is a silicon wafer. The bonding layer may be SiCN for other types of high-resistivity substrate. Certain thermal cycle, such as an anneal process, is needed to facilitate the bonding.

Optionally, before 708, a plurality of thermal dielectric materials (e.g., the plurality of thermal dielectric materials 114) may fill the plurality of trenches. The plurality of thermal dielectric materials may be selected such that the average temperature coefficient of the plurality of dielectric materials and the plurality of piezoelectric islands substantially matches or is close to the temperature coefficient of the high-resistivity substrate and/or the bonding layer. Another good material could be porous dielectric material (Low K) to allow the piezoelectric wafer to expand relatively easily during the bonding annealing.

At 710, a portion of piezoelectric wafer may be removed through exfoliation process. The piezoelectric wafer may first be ground from the back surface to expose the plurality of trenches. Then the piezoelectric wafer may go through another thermal cycle, such as anneal at 100-450° C. temperature to exfoliate along the exfoliation layer. Chemical mechanical polishing (CMP) is further applied to remove the implant damage and to thin the piezoelectric wafer to a desire thickness. As a result, a wafer-level product (e.g., as shown in FIG. 1e, or the product 200 or 300) with a plurality of piezoelectric islands left on top of the high-resistivity substrate through the bonding layer is formed. The plurality of piezoelectric islands is isolated from each other by the plurality of trenches (which may be optionally filled with a thermal dielectric material).

At 712, the wafer-level product is diced to obtain a plurality of dies. Each die forms an individual SAW die (e.g., the individual SAW die 400a, 400b, 500a, or 500b).

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A thin film surface acoustic wave (SAW) die, comprising:
a high-resistivity substrate;
a bonding layer on the high-resistivity substrate; and
a thin film piezoelectric island on the bonding layer, wherein an edge of the thin film piezoelectric island is offset from an edge of the bonding layer.

2. The thin film surface acoustic wave (SAW) die of claim 1 further comprising a thermal dielectric material on the bonding layer surrounding the thin film piezoelectric island.

3. The thin film surface acoustic wave (SAW) die of claim 2, wherein an average temperature coefficient of the thermal dielectric material and the thin film piezoelectric island substantially matches an average temperature coefficient of the high-resistivity substrate.

4. The thin film surface acoustic wave (SAW) die of claim 2, wherein the thermal dielectric material is a low-k material.

5. The thin film surface acoustic wave (SAW) die of claim 1, wherein the thin film piezoelectric island comprises lithium tantalite or lithium niobate.

6. The thin film surface acoustic wave (SAW) die of claim 1, wherein the high-resistivity substrate comprises a high-resistivity silicon.

7. The thin film surface acoustic wave (SAW) die of claim 1, wherein the bonding layer is configured to bond the thin film piezoelectric island to the high-resistivity substrate.

8. The thin film surface acoustic wave (SAW) die of claim 1, wherein the bonding layer comprises an oxide film.

9. An apparatus, comprising:
a high-resistivity substrate;
a bonding layer on the high-resistive substrate; and
a plurality of thin film piezoelectric islands on the bonding layer.

10. The apparatus of claim 9, wherein the plurality of thin film piezoelectric islands is isolated from each other by a plurality of trenches.

11. The apparatus of claim 9 further comprising a plurality of thermal dielectric materials on the bonding layer surrounding each of the plurality of thin film piezoelectric islands.

12. The apparatus of claim 11, wherein an average temperature coefficient of the plurality of thermal dielectric materials and the plurality of thin film piezoelectric island substantially matches an average temperature coefficient of the high-resistivity substrate.

13. The apparatus of claim 11, wherein the thermal dielectric material is a low-k material.

14. The apparatus of claim 9, wherein each of the plurality of thin film piezoelectric islands comprises lithium tantalite or lithium niobate.

15. The apparatus of claim 9, wherein the high-resistivity substrate comprises a high-resistivity silicon.

16. The apparatus of claim 9, wherein the bonding layer is configured to bond the plurality of thin film piezoelectric islands to the high-resistivity substrate.

17. The apparatus of claim 9, wherein each of the plurality of thin film piezoelectric islands is configured to be a thin film surface acoustic wave (SAW) device.

18. The apparatus of claim 9, wherein the bonding layer comprises an oxide film.

19. A method, comprising:
providing a piezoelectric wafer having a front surface and a back surface;
forming an exfoliation layer in the piezoelectric wafer from the front surface;
forming a plurality of trenches on the piezoelectric wafer from the front surface to form a plurality of piezoelectric islands;
bonding the piezoelectric wafer from the front surface to a high-resistivity substrate though a bonding layer; and
removing a portion of the piezoelectric wafer between the back surface and the exfoliation layer.

20. The method of claim 19 further comprising dicing along the plurality of trenches to form a plurality of dies.

21. The method of claim 19, wherein each of the plurality of dies is configured to be a surface acoustic wave (SAW) device.

22. The method of claim 19, further comprising filling the plurality of trenches with a plurality of thermal dielectric materials.

23. The method of claim 19, wherein the piezoelectric wafer comprises lithium tantalite or lithium niobate.

24. The method of claim 19, wherein the high-resistivity substrate comprises a high-resistivity silicon.

25. The method of claim 19 further comprising trimming an edge of the piezoelectric wafer and the bonding layer.
